(19) United States
(12) Patent Application Publication
(10) Pub. No.: US 2025/0210845 A1
(43) Pub. Date: Jun. 26, 2025

(54) APPARATUS AND METHOD FOR DIFFERENTIAL SIGNAL ROUTING

(71) Applicant: IMEC VZW, Leuven (BE)

(72) Inventor: Johan Nguyen, Halle (BE)

(21) Appl. No.: 18/981,444

(22) Filed: Dec. 13, 2024

(30) Foreign Application Priority Data
Dec. 21, 2023 (EP) 23219044.7

(51) Int. Cl. H01P 5/16; H01P 3/08

(52) U.S. Cl. CPC H01P 5/16; H01P 3/08

(57) ABSTRACT

A network of this disclosure comprises a first pair of parallel distribution paths provided on a first metal routing layer, a second pair of parallel distribution paths provided on the first metal routing layer, and a first pair of parallel routing paths provided on a second metal routing layer being orthogonal to the first metal routing layer. In this regard, one path of the first pair of parallel routing paths is connected to one path of the first pair of parallel distribution paths via a first coupling path and further to one path of the second pair of parallel distribution paths via a second coupling path in order to combine or split signals coming from or between the one path of the first pair of parallel distribution paths and the one path of the second pair of parallel distribution paths, respectively.

### CROSS-REFERENCE TO RELATED APPLICATIONS

The present application is a non-provisional patent application claiming priority to European Patent Application No. 23219044.7, filed Dec. 21, 2023, the contents of which are hereby incorporated by reference.

### FIELD OF THE DISCLOSURE

The disclosure relates to differential signal distribution, particularly to splitter or combiner networks for routing high frequency, for example Radio Frequency (RF), differential signals.

### BACKGROUND

The differential signal branching, from the central point of symmetry to multiple signal tapping networks, may be (e.g., carefully) laid out to maintain symmetry. Generally, the symmetrical distribution of wiring has the electrical length of the signal lines being (e.g., always) identical in the two parts, e.g., the positive signal path and the negative signal path, of the differential path, and the capacitive coupling, e.g., to other lines or to the substrate, may be as similar as possible in the two parts of the differential path.

For example, the document U.S. Patent Publication Number 2011/0032065 A1 discloses a symmetrical transformer for differential signaling. U.S. Patent Publication Number 2011/0032065 A1 has a symmetrical distribution of wiring; however, it is not utilized for routing the differential signal to or from the symmetrical transformer, which may affect the signal integrity in terms of imbalance between positive and negative signals.

Accordingly, an object of the disclosure is to provide an apparatus and a method for improving the signal integrity in terms of imbalance between positive and negative signals lines of a differential signal line.

### SUMMARY

The object is implemented as disclosed by the features of the first independent claim for the apparatus and by the features of the second independent claim for the method. The dependent claims contain further developments.

According to a first aspect of the disclosure, an apparatus for differential signal routing is provided. The apparatus comprises a first network comprising a first pair of parallel distribution paths having substantially identical lengths and widths provided on a first metal routing layer, a second pair of parallel distribution paths having substantially identical lengths and widths provided on the first metal routing layer, and a first pair of parallel routing paths having substantially identical lengths and widths provided on a second metal routing layer being orthogonal to the first metal routing layer.

In this regard, one path of the first pair of parallel routing paths is connected to one path of the first pair of parallel distribution paths via a first coupling path comprising a first vertical interconnect access and further to one path of the second pair of parallel distribution paths via a second coupling path comprising a second vertical interconnect access (e.g., in order) to combine or split signals coming from or between the one path of the first pair of parallel distribution paths and the one path of the second pair of parallel distribution paths, respectively.

Furthermore, the other path of the first pair of parallel routing paths is connected to the other path of the first pair of parallel distribution paths via a third coupling path comprising a third vertical interconnect access and further to the other path of the second pair of parallel distribution paths via a fourth coupling path comprising a fourth vertical interconnect access in order to combine or split signals coming from or between the other path of the first pair of parallel distribution paths and the other path of the second pair of parallel distribution paths, respectively.

Moreover, at least the first coupling path and the third coupling path have substantially identical lengths and widths, and at least the second coupling path and the fourth coupling path have substantially identical lengths and widths. In an example embodiment, e.g., for splitting or for combining differential signals, an imbalance between the positive signal and the negative signal of the differential signal can be (e.g., drastically) reduced by utilizing extreme symmetry between the positive signal path and the negative signal path, thereby improving the signal integrity.

In an example embodiment, the first metal routing layer and the second metal routing layer correspond to back-end-of-line (BEOL) metallization structures. For example, the BEOL metallization structure may be a part of an integrated circuit, (e.g., especially) comprising semiconductor based wafers with planar layers. The integrated circuit may further comprise a front-end-of-line (FEOL) with active devices, such as transistors, and the BEOL for signal routing.

For example, the first metal routing layer and the second metal routing layer may be adjacent metal layers or levels of the planar integrated circuit BEOL metallization structure. In this regard, (e.g., each of) the vertical interconnect accesses may provide a vertical electrically conductive connection between the first metal routing layer and the second metal routing layer, thereby electrically connecting the first metal routing layer to the second metal routing layer. The first metal routing layer and the second metal routing layer may not be adjacent metal layers or levels of the planar integrated circuit BEOL metallization structure. In this regard, (e.g., each of) the vertical interconnect accesses may provide a vertical electrically conductive connection between the first metal routing layer and the second metal routing layer covering more layers, this is achieved by super-VIA's. The super-VIA thereby electrically connecting the first metal routing layer to the non-adjacent second metal routing layer.

The vertical interconnect accesses vertically connect the metal layers which are in a horizontal plane. So the vertical interconnect accesses are orthogonal and upward/downward oriented with respect to the metal layers.

In an example embodiment, each of the first coupling path and the third coupling path comprises a number of turns identical to each other. Additionally or alternatively, each of the second coupling path and the fourth coupling path comprises a number of turns identical to each other.

In an example embodiment, the first coupling path, the second coupling path, the third coupling path, and the fourth coupling path have substantially identical lengths and widths, and identical number of turns. For example, the symmetry between the positive signal path and the negative signal path for each of the first pair of parallel distribution paths and the second pair of parallel distribution paths can be maintained.

In an example embodiment, the first coupling path, the second coupling path, the third coupling path, and the fourth coupling path have an identical number of 45 degrees turns. In other words, the number of turns for each of the coupling paths may be substantially identical to each other. In an example embodiment, the number of turns may comprise one or more turns between 40 degrees and 50 degrees, or between 42 degrees and 48 degrees, or between 44 degrees and 46 degrees, or one or more 45 degrees turns.

In an example embodiment, the first coupling path, the second coupling path, the third coupling path, and the fourth coupling path have identical number of 90 degrees turns. In other words, the number of turns for each of the coupling paths may be identical to each other. In an example embodiment, the number of turns may comprise one or more turns between 85 degrees and 95 degrees, or between 87 degrees and 93 degrees, or between 89 degrees and 91 degrees, or one or more 90 degrees turns.

Alternatively, the number of turns may comprise one or more 22.5 degrees turns or other polygon shapes.

In an example embodiment, the one path of the first pair of parallel routing paths and the first pair of parallel distribution paths overlap at their respective cross-sections. In addition, the other path of the first pair of parallel routing paths and the second pair of parallel distribution paths overlap at their respective cross-sections.

In an example embodiment, the one path of the first pair of parallel routing paths and the first pair of parallel distribution paths may overlap at their respective cross-sections such that both the positive signal path and the negative signal path may operate with similar amount of capacitive coupling between them, e.g., formed at their respective cross-sections.

Similarly, the other path of the first pair of parallel routing paths and the second pair of parallel distribution paths may overlap at their respective cross-sections such that both the positive signal path and the negative signal path may operate with similar amount of capacitive coupling between them, e.g., formed at their respective cross-sections.

In an example embodiment, the apparatus further comprises at least one second network. The second network comprises a second pair of parallel routing paths having substantially identical lengths and widths provided on the second metal routing layer, and a pair of vertical interconnect accesses being symmetrically arranged on the first metal routing layer with respect to the lengths of the first pair of parallel distribution paths or the second pair of parallel distribution paths, wherein each vertical interconnect access of the pair of vertical interconnect accesses is arranged on a respective distribution path of the first pair of parallel distribution paths or the second pair of parallel distribution paths.

In an example embodiment, the second pair of parallel routing paths are respectively connected to the pair of vertical interconnect accesses via a pair of coupling paths having substantially identical lengths and widths provided on the second metal routing layer, the pair of coupling paths being symmetrically connected to the second pair of parallel routing paths with respect to the lengths of the second pair of parallel routing paths in order to couple in or out a differential signal to or from the first pair of parallel distribution paths or the second pair of parallel distribution paths, respectively.

In an example embodiment, e.g., for coupling in or for coupling out the differential signal, an imbalance between the positive signal and the negative signal of a differential signal can be drastically reduced by utilizing extreme symmetry between the positive signal path and the negative signal path, thereby improving the signal integrity. The second network allows to make a 90 degrees turn in both of the differential signal paths.

In an example embodiment, the widths of the second pair of parallel routing paths and the widths of the pair of coupling paths are substantially identical to each other. Alternatively, the widths of the second pair of parallel routing paths and the widths of the pair of coupling paths are different from each other.

In an example embodiment, for example, the different coupling paths can be formed in a flexible manner (e.g., within the design rule), e.g., to meet a (e.g., certain) area constraint, whereby maintain the symmetry between the positive signal path and the negative signal path.

In an example embodiment, each path of the pair of coupling paths comprises a number of turns identical to each other, such as a number of 45 degrees turns. In other words, the number of turns for each of the coupling paths may be identical to each other. The number of turns may comprise one or more turns between 40 degrees and 50 degrees, or between 42 degrees and 48 degrees, or between 44 degrees and 46 degrees, or one or more 45 degrees turns.

In an example embodiment, each path of the pair of coupling paths comprises a number of turns identical to each other, such as a number of 90 degrees turns. In other words, the number of turns for each of the coupling paths may be identical to each other. The number of turns may comprise one or more turns between 85 degrees and 95 degrees, or between 87 degrees and 93 degrees, or between 89 degrees and 91 degrees, or one or more 90 degrees turns.

Alternatively, the number of turns may comprise one or more 22.5 degrees turns or other polygon shapes.

In an example embodiment, the second pair of parallel routing paths and the first pair of parallel distribution paths or the second pair of parallel distribution paths overlap at their respective cross-sections.

In an example embodiment, the second pair of parallel routing paths and the first pair of parallel distribution paths, or the second pair of parallel routing paths and the second pair of parallel distribution paths, may overlap at their respective cross-sections such that both the positive signal path and the negative signal path may operate with similar amount of capacitive coupling, e.g., formed at their respective cross-sections.

According to a second aspect of the disclosure, a method is provided for differential signal routing. The method comprises a step of forming a first pair of parallel distribution paths having substantially identical lengths and widths on a first metal routing layer. The method further comprises a step of forming a second pair of parallel distribution paths having substantially identical lengths and widths on the first metal routing layer. Moreover, the method comprises a step of forming a first pair of parallel routing paths having substantially identical lengths and widths provided on a second metal routing layer being orthogonal to the first metal routing layer.

The method further comprises a step of connecting one path of the first pair of parallel routing paths to one path of the first pair of parallel distribution paths via a first coupling path comprising a first vertical interconnect access and further to one path of the second pair of parallel distribution paths via a second coupling path comprising a second vertical interconnect access.

In addition, the method comprises a step of connecting other path of the first pair of parallel routing paths to other path of the first pair of parallel distribution paths via a third coupling path comprising a third vertical interconnect access and further to other path of the second pair of parallel distribution paths via a fourth coupling path comprising a fourth vertical interconnect access.

Furthermore, the method comprises a step of combining or splitting signals coming from or between the one path of the first pair of parallel distribution paths and the one path of the second pair of parallel distribution paths, respectively, by the one path of the first pair of parallel routing paths.

Moreover, the method comprises a step of combining or splitting signals coming from or between the other path of the first pair of parallel distribution paths and the other path of the second pair of parallel distribution paths, respectively, by the other path of the first pair of parallel routing paths.

In an example embodiment, the method further comprises a step of forming a second pair of parallel routing paths having substantially identical lengths and widths on the second metal routing layer.

In addition, the method comprises a step of symmetrically arranging a pair of vertical interconnect accesses on the first metal routing layer with respect to the lengths of the first pair of parallel distribution paths or the second pair of parallel distribution paths such that each vertical interconnect access of the pair of vertical interconnect accesses is arranged on a respective distribution path of the first pair of parallel distribution paths or the second pair of parallel distribution paths.

Furthermore, the method comprises a step of forming a pair of coupling paths having substantially identical lengths and widths on the second metal routing layer such that the pair of coupling paths being symmetrically connected to the second pair of parallel routing paths with respect to the lengths of the second pair of parallel routing paths.

Moreover, the method comprises a step of respectively connecting the second pair of parallel routing paths to the pair of vertical interconnect accesses via the pair of coupling paths in order to couple in or out a differential signal to or from the first pair of parallel distribution paths or the second pair of parallel distribution paths, respectively.

The term “substantially identical” can be understood as having an identical property between multiple entities. Alternatively, the term “substantially identical” can be understood as having a property with a difference less than 10%, or less than 5%, or less than 2%, or less than 1% between multiple entities.

It is to be noted that the method according to the second aspect corresponds to the apparatus according to the first aspect and its implementation forms. Accordingly, the method of the second aspect may have corresponding implementation forms. Further, the method of the second aspect achieves the same usefulness as the apparatus of the first aspect and its respective implementation forms.

### BRIEF DESCRIPTION OF THE FIGURES

The above, as well as additional, features will be better understood through the following illustrative and non-limiting detailed description of example embodiments, with reference to the appended drawings.

Exemplary embodiments of the disclosure are now further explained with respect to the drawings by way of example (e.g., only), and not for limitation. In the drawings:

FIG. 1 shows an exemplary embodiment of the apparatus;

FIG. 2 shows a first exemplary embodiment of the first network;

FIG. 3 shows a second exemplary embodiment of the first network

FIG. 4 shows an exemplary signal flow for the network of FIG. 3;

FIG. 5 shows a first exemplary embodiment of the second network;

FIG. 6 shows a second exemplary embodiment of the second network;

FIG. 7 shows an exemplary signal flow for the network of FIG. 6; and

FIG. 8 shows an exemplary embodiment of the method.

The figures are schematic, may not be to scale, and generally (e.g., only) show parts which elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

Reference will now be made in detail to the embodiments of the present disclosure, examples of which are illustrated in the accompanying drawings. However, the following embodiments of the present disclosure may be variously modified and the range of the present disclosure is not limited by the following embodiments.

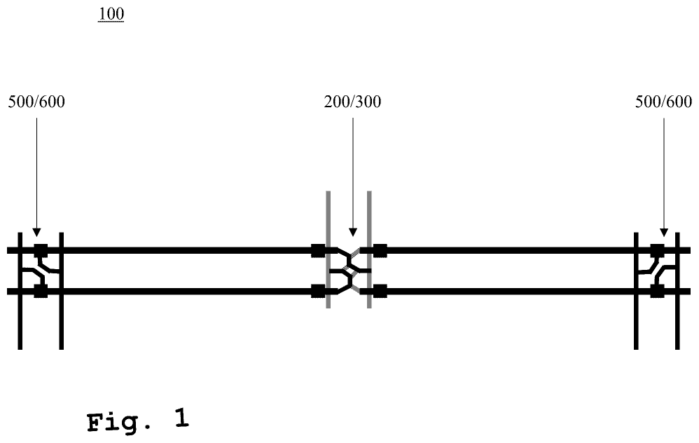

In FIG. 1, an exemplary embodiment of the apparatus 100 according to the first aspect of the disclosure is illustrated. The apparatus 100 may correspond to a signal splitter or a signal combiner for splitting or combining differential signals, respectively.

As the frequency of the signals in a signal distribution is increased, capacitive and inductive effect may become more dominant. The capacitance and inductance of the signal paths as well as the coupling and parasitic versions of both may become more pronounced and even dominant. Mismatches in the above mentioned paths will lead to erroneous behavior of the circuits connected to the signal distribution network. To minimize common mode effects differential signal distribution is often used in high frequency applications, for example RF. The embodiments described below provide for differential signal distribution to further minimize the impact of capacitive and inductive elements (e.g., inherent) to any signal distribution system.

For instance, the apparatus 100 may comprise a central network 200, 300 for splitting a differential signal onto two differential signal transmission lines or for combining differential signals coming from the two differential signal transmission lines. The apparatus 100 may further comprise two corner networks 500, 600 for routing the differential signals from the respective differential signal transmission lines, e.g., to or from a respective load. It is to be noted that the number of second or corner networks 500, 600 can be less than or more than two.

For example, the central network 200, 300 may be arranged to facilitate a central point of symmetry with respect to the corner splitters of the second networks 500, 600, and symmetrical interconnection for the corner splitters of the second networks 500, 600 from the central point of symmetry may be maintained for an equivalent electrical length, width, and capacitive coupling in the respective positive and the negative paths of the differential signal transmission lines.

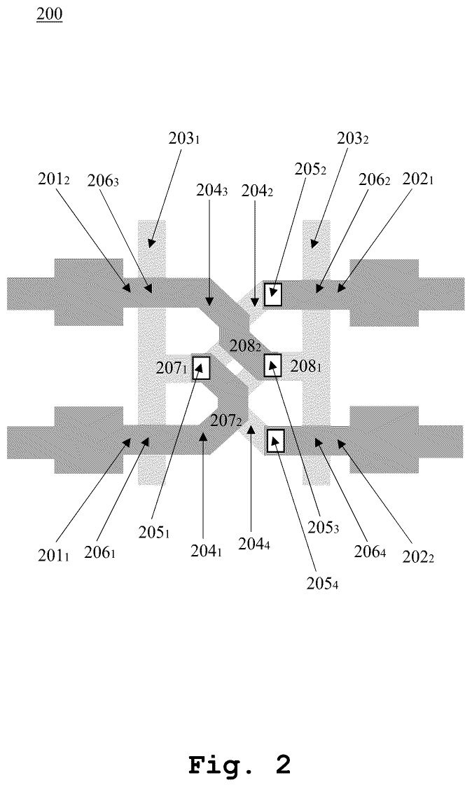

In FIG. 2, a first exemplary embodiment of the first network 200 according to the first aspect of the disclosure is illustrated. The first network 200 may correspond to the central network of FIG. 1.

For example, the first network 200 may comprise a first pair of distribution paths comprising a first path 2011 and a second path 2012, e.g., one for the positive signal (p-path) and the other for the negative signal (n-path) of the differential signal. In an example embodiment, the first path 2011 and the second path 2012 of the first pair of distribution paths may have identical lengths and widths.

In this regard, the length of each of the first path 2011 and the second path 2012 of the first pair of distribution paths may correspond to the length or horizontal distance between the central network and one of the corner networks of FIG. 1, e.g., between the respective signal tapping points, for symmetry in the horizontal signal distribution. For instance, the first path 2011 and the second path 2012 of the first pair of distribution paths may be provided on a first (M1) metal routing layer.

For instance, the first network 200 may comprise a second pair of distribution paths comprising a first path 2021 and a second path 2022, e.g., one for the positive signal (p-path) and the other for the negative signal (n-path) of the differential signal. In an example embodiment, the first path 2021 and the second path 2022 of the second pair of distribution paths may have identical lengths and widths.

In this regard, the length of each of the first path 2021 and the second path 2022 of the second pair of distribution paths may correspond to the length or horizontal distance between the central network and one of the corner networks of FIG. 1, e.g., between the respective signal tapping points, for symmetry in the horizontal signal distribution. For instance, the first path 2021 and the second path 2022 of the second pair of distribution paths may be provided on the M1 metal routing layer.

For example, the first network 200 may comprise a pair of routing paths comprising a first path 2031 and a second path 2032, e.g., one for the positive signal (p-path) and the other for the negative signal (n-path) of the differential signal. In an example embodiment, the first path 2031 and the second path 2032 of the pair of routing paths may have identical lengths and widths. For instance, the first path 2031 and the second path 2032 of the pair of routing paths may be provided on a second (M2) metal routing layer.

In this regard, the M2 metal routing direction of the M2 routing layer may be orthogonal to the M1 metal routing direction of the M1 routing layer. This orthogonality is in the horizontal plane in which the metal layers are formed in for example integrated circuits (IC), more particularly CMOS IC's. It may be noted that the coupling paths are not restricted to the orthogonal restriction of the routing direction. As the coupling paths may comprise turns of 22.5, 45, or 90 degrees. Further the coupling paths may also comprise polygon shapes of other and multiple angles forming curves or bends if the integration technology allows for that. In an example embodiment, the M1 metal routing layer and the M2 metal routing layer may be adjacent metal routing layers. The first and second metal layers can be interchanged. The first and second metal layers may be layers with other metal layers in between the first and second metal layers. In these embodiments, the vertical interconnect accesses are covering multiple metal layers to cover the distance between the first and the second layer, achieved by super-VIA's. The VIA's or super-VIA's are vertical interconnect structures e.g., are orthogonal to the plane of the metal layers in planar integration technologies for fabricating IC's.

In an example embodiment, the first path 2031 of the pair of routing paths may be connected to the first path 2011 of the first pair of distribution paths via a first coupling path 2041. In this regard, a first vertical interconnect access (VIA) 2051 may be arranged on the first coupling path 2041 to vertically connect the M1 metal routing layer and the M2 metal routing layer, thereby interconnecting the first path 2031 of the pair of routing paths and the first path 2011 of the first pair of distribution paths.

For example, the first coupling path 2041 may comprise four successive 45 degrees turns. However, the first coupling path 2041 may comprise more than or less than four 45 degrees turns. Alternatively, the first coupling path 2041 may comprise a number of successive 22.5 degrees turns. Alternatively, the first coupling path 2041 may be provided in any polygon shapes that can be achieved (e.g., within the design rule).

For instance, the first path 2031 of the pair of routing paths may be further connected to the first path 2021 of the second pair of distribution paths via a second coupling path 2042. In this regard, a second VIA 2052 may be arranged on the second coupling path 2042 to vertically connect the M1 metal routing layer and the M2 metal routing layer, thereby interconnecting the first path 2031 of the pair of routing paths and the first path 2021 of the second pair of distribution paths.

For example, the second coupling path 2042 may comprise four successive 45 degrees turns. However, the second coupling path 2042 may comprise more than or less than four 45 degrees turns. Alternatively, the second coupling path 2042 may comprise a number of successive 22.5 degrees turns. Alternatively, the second coupling path 2042 may be provided in any polygon shapes that can be achieved (e.g., within the design rule).

In this regard, the first path 2031 of the pair of routing paths may combine or split signals coming from or between the first path 2011 of the first pair of distribution paths and the first path 2021 of the second pair of distribution paths, respectively.

For instance, the second path 2032 of the pair of routing paths may be connected to the second path 2012 of the first pair of distribution paths via a third coupling path 2043. In this regard, a third VIA 2053 may be arranged on the third coupling path 2043 to vertically connect the M1 metal routing layer and the M2 metal routing layer, thereby interconnecting the second path 2032 of the pair of routing paths and the second path 2012 of the first pair of distribution paths.

For example, the third coupling path 2043 may comprise four successive 45 degrees turns. However, the third coupling path 2043 may comprise more than or less than four 45 degrees turns. Alternatively, the third coupling path 2043 may comprise a number of successive 22.5 degrees turns. Alternatively, the third coupling path 2043 may be provided in any polygon shapes that can be achieved (e.g., within the design rule).

For instance, the second path 2032 of the pair of routing paths may be further connected to the second path 2022 of the second pair of distribution paths via a fourth coupling path 2044. In this regard, a fourth VIA 2054 may be arranged on the fourth coupling path 2044 to vertically connect the M1 metal routing layer and the M2 metal routing layer, thereby interconnecting the second path 2032 of the pair of routing paths and the second path 2022 of the second pair of distribution paths.

For example, the fourth coupling path 2044 may comprise four successive 45 degrees turns. However, the fourth coupling path 2044 may comprise more than or less than four 45 degrees turns. Alternatively, the fourth coupling path 2044 may comprise a number of successive 22.5 degrees turns. Alternatively, the fourth coupling path 2044 may be provided in any polygon shapes.

In this regard, the second path 2032 of the pair of routing paths may combine or split signals coming from or between the second path 2012 of the first pair of distribution paths and the second path 2022 of the second pair of distribution paths, respectively.

In an example embodiment, the first coupling path 2041 and the third coupling path 2043 may have identical lengths, identical widths, identical number of turns, and/or identical polygon shapes. Additionally, the second coupling path 2042 and the fourth coupling path 2044 may have identical lengths, identical widths, identical number of turns, and/or identical polygon shapes.

In an example embodiment, the first coupling path 2041, the second coupling path 2042, the third coupling path 2043, and the fourth coupling path 2044 may have identical lengths, identical widths, identical number of turns, and/or identical polygon shapes.

For example, the first coupling path 2041 may comprise a first portion 2071 provided on the M2 metal layer being connected to the first path 2031 of the pair of routing paths. The first coupling path 2041 may further comprise a second portion 2072 provided on the M1 metal layer being connected to the first path 2011 of the first pair of distribution paths. In this regard, the first VIA 2051 may interconnect the first portion 2071 and the second portion 2072 of the first coupling path 2041.

For instance, the second coupling path 2042 may be provided on the M2 metal layer being connected to the first path 2031 of the pair of routing paths, e.g., forming a common branching point for both the first coupling path 2041 and the second coupling path 2042 from the first path 2031 of the pair of routing paths. In this regard, the second VIA 2052 may interconnect the second coupling path 2042 and the first path 2021 of the second pair of distribution paths.

For example, the third coupling path 2043 may comprise a first portion 2081 provided on the M2 metal layer being connected to the second path 2032 of the pair of routing paths. The third coupling path 2043 may further comprise a second portion 2082 provided on the M1 metal layer being connected to the second path 2012 of the first pair of distribution paths. In this regard, the third VIA 2053 may interconnect the first portion 2081 and the second portion 2082 of the third coupling path 2043.

For instance, the fourth coupling path 2044 may be provided on the M2 metal layer being connected to the second path 2032 of the pair of routing paths, e.g., forming a common branching point for both the third coupling path 2043 and the fourth coupling path 2044 from the second path 2032 of the pair of routing paths. In this regard, the fourth VIA 2054 may interconnect the fourth coupling path 2044 and the second path 2022 of the second pair of distribution paths.

In an example embodiment, the common branching point on the first path 2031 of the pair of routing paths and the common branching point on the second path 2032 of the pair of routing paths may be provided in a symmetrical manner with respect to the lengths of the pair of routing paths, e.g., at a distance along the length of each path of the pair of routing paths that is equivalent or identical to each other.

For example, the first path 2031 of the pair of routing paths and the first path 2011 of the first pair of distribution paths may overlap at a first cross-section 2061. In addition, the second path 2032 of the pair of routing paths and the first path 2021 of the second pair of distribution paths may overlap at a second cross-section 2062.

Furthermore, the first path 2031 of the pair of routing paths and the second path 2012 of the first pair of distribution paths may overlap at a third cross-section 2063. Moreover, the second path 2032 of the pair of routing paths and the second path 2022 of the second pair of distribution paths may overlap at a fourth cross-section 2064.

In this regard, at the first cross-section 2061, the first path 2031 of the pair of routing paths and the first path 2011 of the first pair of distribution paths may operate in-phase, which may result in the coupling capacitance between two in-phase signals. In addition, at the second cross-section 2062, the second path 2032 of the pair of routing paths and the first path 2021 of the second pair of distribution paths may operate in antiphase, which may provide the coupling capacitance between two antiphase signals.

Furthermore, at the third cross-section 2063, the first path 2031 of the pair of routing paths and the second path 2012 of the first pair of distribution paths may operate in antiphase, which may provide the coupling capacitance between two antiphase signals. Moreover, at the fourth cross-section 2064, the second path 2032 of the pair of routing paths and the second path 2022 of the second pair of distribution paths may operate in-phase, which may provide the coupling capacitance between two in-phase signals.

In other words, the differential signal path from the first path 2031 of the pair of routing paths to the first path 2011 of the first pair of distribution paths via the first coupling path 2041 and the differential signal path from the second path 2032 of the pair of routing paths to the second path 2012 of the first pair of distribution paths via the third coupling path 2043 may have an equivalent electrical length, width, line inductance, and an equivalent amount of coupling capacitance.

Similarly, the differential signal path from the first path 2031 of the pair of routing paths to the first path 2021 of the second pair of distribution paths via the second coupling path 2042 and the differential signal path from the second path 2032 of the pair of routing paths to the second path 2022 of the second pair of distribution paths via the fourth coupling path 2044 may have an equivalent electrical length, width, line inductance, and an equivalent amount of coupling capacitance.

Therefore, due to the extreme symmetry between the p-path and the n-path of the differential signal paths, equivalent electrical length, width, line inductance, and an equivalent amount of coupling capacitance can be achieved for the p-path and the n-path, thereby improving the signal integrity.

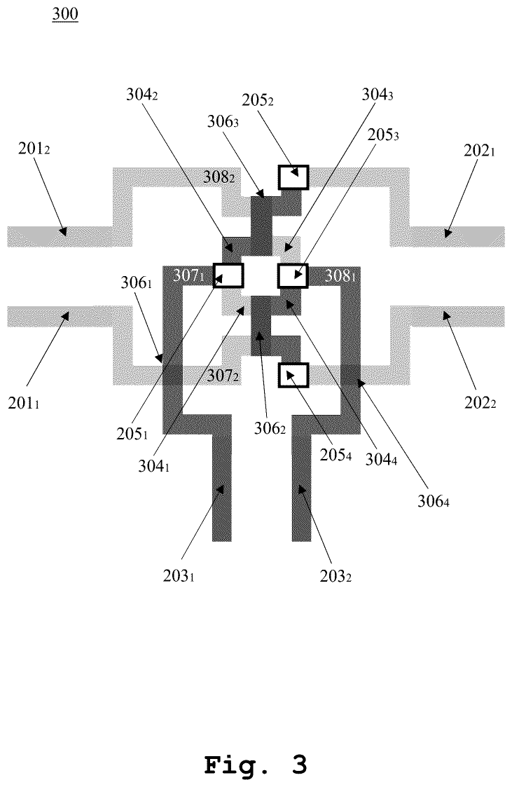

In FIG. 3, a second exemplary embodiment of the first network 300 according to the first aspect of the disclosure is illustrated. The first network 300 may correspond to the central network of FIG. 1. The first network 300 may differ from the first network 200 in that the first coupling path 3041, the second coupling path 3042, the third coupling path 3043, and the fourth coupling path 3044 may have a number of consecutive 90 degrees turns.

For example, the first coupling path 3041 may comprise a first portion 3071 provided on the M2 metal layer (shown as darker grayscale) by extending the first path 2031 of the pair of routing paths. The first coupling path 3041 may further comprise a second portion 3072 provided on the M1 metal layer (shown as lighter grayscale) being extended from the first path 2011 of the first pair of distribution paths. In this regard, the first VIA 2051 may interconnect the first portion 3071 and the second portion 3072 of the first coupling path 3041.

For instance, the second coupling path 3042 may be provided on the M2 metal layer by extending the first path 2031 of the pair of routing paths, e.g., forming a common branching point for both the first coupling path 3041 and the second coupling path 3042 at the first VIA 2051. In this regard, the second VIA 2052 may interconnect the second coupling path 3042 and the first path 2021 of the second pair of distribution paths.

For example, the third coupling path 3043 may comprise a first portion 3081 provided on the M2 metal layer by extending the second path 2032 of the pair of routing paths. The third coupling path 3043 may further comprise a second portion 3082 provided on the M1 metal layer being extended from the second path 2012 of the first pair of distribution paths. In this regard, the third VIA 2053 may interconnect the first portion 3081 and the second portion 3082 of the third coupling path 3043.

For instance, the fourth coupling path 3044 may be provided on the M2 metal layer by extending the second path 2032 of the pair of routing paths, e.g., forming a common branching point for both the third coupling path 3043 and the fourth coupling path 3044 at the third VIA 2053. In this regard, the fourth VIA 4054 may interconnect the fourth coupling path 3044 and the second path 2022 of the second pair of distribution paths.

In an example embodiment, the first coupling path 3041 and the third coupling path 3043 may have identical lengths, identical widths, identical number of turns, and/or identical shapes. Additionally, the second coupling path 3042 and the fourth coupling path 3044 may have identical lengths, identical widths, identical number of turns, and/or identical shapes.

In an example embodiment, the first coupling path 3041, the second coupling path 3042, the third coupling path 3043, and the fourth coupling path 3044 may have identical lengths, identical widths, identical number of turns, and/or identical shapes.

For example, the first portion 3071 and the second portion 3072 of the first coupling path 3041 may overlap at a first cross-section 3061. In addition, the second portion 3072 of the first coupling path 3041 and the fourth coupling path 3044 may overlap at a second cross-section 3062. Furthermore, the second coupling path 3042 and the second portion 3082 of the third coupling path 3043 may overlap at a third cross-section 3063. Moreover, the first portion 3081 of the third coupling path 3043 and the fourth coupling path 3044 may overlap at a fourth cross-section 3064.

In this regard, at the first cross-section 3061, the crossed-over paths may operate in-phase, which may provide the coupling capacitance between two in-phase signals. In addition, at the second cross-section 3062, the crossed-over paths may operate in antiphase, which may provide the coupling capacitance between two antiphase signals. Furthermore, at the third cross-section 3063, the crossed-over paths may operate in antiphase, which may provide the coupling capacitance between two antiphase signals. Moreover, at the fourth cross-section 3064, the crossed-over paths may operate in-phase, which may provide the coupling capacitance between two in-phase signals.

In other words, the differential signal path from the first path 2031 of the pair of routing paths to the first path 2011 of the first pair of distribution paths via the first coupling path 3041 and the differential signal path from the second path 2032 of the pair of routing paths to the second path 2012 of the first pair of distribution paths via the third coupling path 3043 may have an equivalent electrical length, width, line inductance, and an equivalent amount of coupling capacitance.

Similarly, the differential signal path from the first path 2031 of the pair of routing paths to the first path 2021 of the second pair of distribution paths via the second coupling path 3042 and the differential signal path from the second path 2032 of the pair of routing paths to the second path 2022 of the second pair of distribution paths via the fourth coupling path 3044 may have an equivalent electrical length, width, line inductance, and an equivalent amount of coupling capacitance.

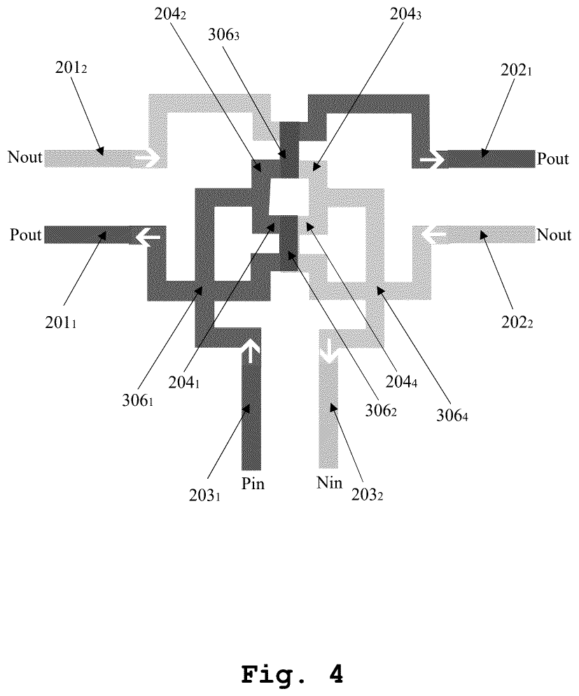

In FIG. 4, an exemplary signal flow for the network 300 is illustrated. In particular, a split operation of a differential signal Pin, Nin from the pair of routing paths 2031, 2032 to the first pair of distribution paths 2011, 2012 and the second pair of distribution path 2021, 2022 is illustrated. In this example, the p-path is shown in the darker grayscale and the n-path is shown in the lighter grayscale.

The positive signal Pin may be inputted from the first path 2031 of the pair of routing paths and may be split between the first path 2011 of the first pair of distribution paths and the first path 2021 of the second pair of distribution paths (shown as Pout). Similarly, the negative signal Nin may be inputted from the second path 2032 of the pair of routing paths and may be split between the second path 2012 of the first pair of distribution paths and the second path 2022 of the second pair of distribution paths (shown as Nout).

It can be seen that the signal path Pin-Pout from the first path 2031 of the pair of routing paths to the first path 2011 of the first pair of distribution paths and the signal path Nin-Nout from the second path 2032 of the pair of routing paths to the second path 2012 of the first pair of distribution paths may have an equivalent electrical length, width, line inductance, and an equivalent amount of coupling capacitance.

Similarly, the signal path Pin-Pout from the first path 2031 of the pair of routing paths to the first path 2021 of the second pair of distribution paths and the signal path Nin-Nout from the second path 2032 of the pair of routing paths to the second path 2022 of the second pair of distribution paths may have an equivalent electrical length, width, line inductance, and an equivalent amount of coupling capacitance.

It will be clear for the skilled person that if, in FIG. 4., the inputs and outputs are interchanged and the signal direction indicated by the arrows are in the opposite direction then the signal splitter operation will change to a signal combiner.

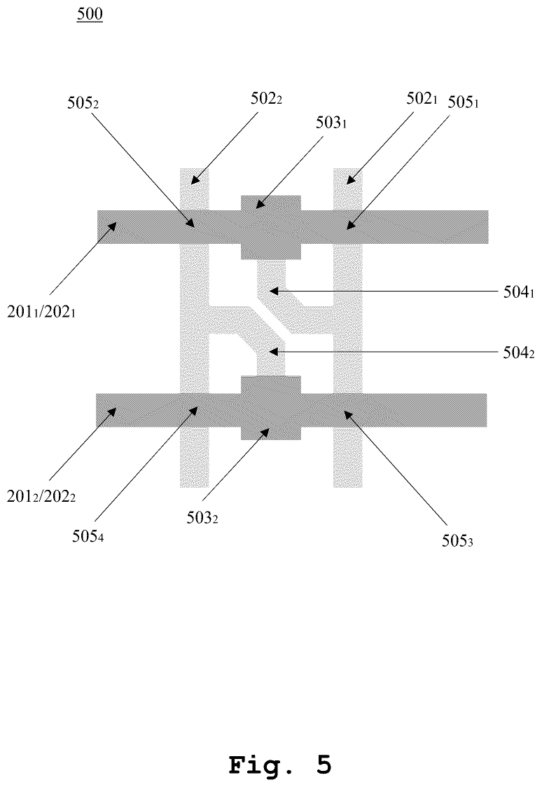

In FIG. 5, a first exemplary embodiment of the second network 500 according to the first aspect of the disclosure is illustrated. The second network 500 may correspond to the corner network of FIG. 1.

For example, the second network 500 may comprise a pair of distribution paths. The pair of distribution paths may correspond to the first pair of distribution paths 2011, 2012 or the second pair of distribution paths 2021, 2022 of the first network 200, 300 as shown in FIG. 2 to FIG. 4. It is to be noted, in the following, (e.g., only) the first pair of distribution paths 2011, 2012 is considered, and the implementation is similar for the second pair of distribution paths 2021, 2022.

As mentioned before, the pair of distribution paths may comprise the first path 2011 and the second path 2012, e.g., one for the positive signal (p-path) and the other for the negative signal (n-path) of the differential signal, which may have identical lengths and widths.

In this regard, the length of each of the first path 2011 and the second path 2012 of the pair of distribution paths may correspond to the length or horizontal distance between the central network and one of the corner networks of FIG. 1, e.g., between the respective signal tapping points, for symmetry in the horizontal signal distribution. Furthermore, the first path 2011 and the second path 2012 of the pair of distribution paths may be provided on the M1 metal routing layer.

For example, the second network 500 may comprise a pair of routing paths comprising a first path 5021 and a second path 5022, e.g., one for the positive signal (p-path) and the other for the negative signal (n-path) of the differential signal. In an example embodiment, the first path 5021 and the second path 5022 of the pair of routing paths may have identical lengths and widths. For instance, the first path 5021 and the second path 5022 of the pair of routing paths may be provided on the M2 metal routing layer.

As mentioned before, the signal routing direction of the signal paths in the M2 metal routing layer may be orthogonal to the signal routing direction of the signal paths in the M1 metal routing layer. In an example embodiment, the M1 metal routing layer and the M2 metal routing layer may be adjacent metal routing layers.

For instance, the first path 5021 of the pair of routing paths may be connected to the first path 2011 of the pair of distribution paths via a first coupling path 5041. The first coupling path 5041 may be provided on the M2 metal routing layer being connected to the first path 5021 of the pair of routing paths and further to the first path 2011 of the pair of distribution paths through a first VIA 5031.

The first VIA 5031 may be arranged on the first path 2011 of the pair of distribution paths to vertically connect the M1 metal routing layer and the M2 metal routing layer, thereby interconnecting the first coupling path 5041 and the first path 2011 of the pair of distribution paths.

For example, the second path 5022 of the pair of routing paths may be connected to the second path 2012 of the pair of distribution paths via a second coupling path 5042. The second coupling path 5042 may be provided on the M2 metal routing layer being connected to the second path 5022 of the pair of routing paths and further to the second path 2012 of the pair of distribution paths through a second VIA 5032.

In this regard, the second VIA 5032 may be arranged on the second path 2012 of the pair of distribution paths to vertically connect the M1 metal routing layer and the M2 metal routing layer, thereby interconnecting the second coupling path 5042 and the second path 2012 of the first of distribution paths.

For example, the first path 5021 of the pair of routing paths may route a signal to or from the first path 2011 of the pair of distribution paths via the first coupling path 5041 and the second path 5022 of the pair of routing paths may route a signal to or from the second path 2012 of the pair of distribution paths via the second coupling path 5042.

For example, the first coupling path 5041 and the second coupling path 5042 may be connected to the first path 5021 of the pair of routing paths and the second path 5022 of the pair of routing paths, respectively, at points symmetrical to each other, e.g., at a distance along the length of each path of the pair of routing paths that is equivalent or identical to each other.

In addition, the first VIA 5031 and the second VIA 5032 may be arranged on the first path 2011 of the pair of distribution paths and the second path 2012 of the pair of distribution paths, respectively, at points symmetrical to each other, e.g., at a distance along the length of each path of the pair of distribution paths that is equivalent or identical to each other.

For example, the first coupling path 5041 may comprise two successive 45 degrees turns. However, the first coupling path 5041 may comprise more than or less than two 45 degrees turns. Alternatively, the first coupling path 5041 may comprise a number of successive 22.5 degrees turns. Alternatively, the first coupling path 5041 may be provided in any polygon shapes that can be achieved (e.g., within the design rule).

In addition, the second coupling path 5042 may comprise two successive 45 degrees turns. However, the second coupling path 5042 may comprise more than or less than two 45 degrees turns. Alternatively, the second coupling path 5042 may comprise a number of successive 22.5 degrees turns. Alternatively, the second coupling path 5042 may be provided in any polygon shapes that can be achieved (e.g., within the design rule).

For example, the first coupling path 5041 and the first path 5021 of the pair of routing paths may have identical widths. In addition, the second coupling path 5042 and the second path 5022 of the pair of routing paths may have identical widths. In an example embodiment, the first coupling path 5041 and the second coupling path 5042 may have identical lengths, widths, identical number of turns, and/or identical polygon shapes.

For example, the first path 5021 of the pair of routing paths and the first path 2011 of the pair of distribution paths may overlap at a first cross-section 5051. In addition, the second path 5022 of the pair of routing paths and the first path 2011 of the pair of distribution paths may overlap at a second cross-section 5052.

Furthermore, the first path 5021 of the pair of routing paths and the second path 2012 of the pair of distribution paths may overlap at a third cross-section 5053. Moreover, the second path 5022 of the pair of routing paths and the second path 2022 of the pair of distribution paths may overlap at a fourth cross-section 5054.

In this regard, at the first cross-section 5051, the first path 5021 of the pair of routing paths and the first path 2011 of the pair of distribution paths may operate in-phase, which may provide the coupling capacitance between two in-phase signals. In addition, at the second cross-section 5052, the second path 5022 of the pair of routing paths and the first path 2011 of the pair of distribution paths may operate in antiphase, which may provide the coupling capacitance between two antiphase signals.

Furthermore, at the third cross-section 5053, the first path 5021 of the pair of routing paths and the second path 2012 of the pair of distribution paths may operate in antiphase, which may provide the coupling capacitance between two antiphase signals. Moreover, at the fourth cross-section 5054, the second path 5022 of the pair of routing paths and the second path 2022 of the pair of distribution paths may operate in-phase, which may provide the coupling capacitance between two in-phase signals.

In other words, the differential signal path from the first path 5021 of the pair of routing paths to the first path 2011 of the pair of distribution paths via the first coupling path 5041 and the differential signal path from the second path 5022 of the pair of routing paths to the second path 2012 of the pair of distribution paths via the second coupling path 5042 may have an equivalent electrical length, width, line inductance, and an equivalent amount of coupling capacitance. Therefore, due to the extreme symmetry between the p-path and the n-path of the differential signal paths, equivalent electrical length, width, line inductance, and an equivalent amount of coupling capacitance can be achieved for the p-path and the n-path, thereby improving the signal integrity.

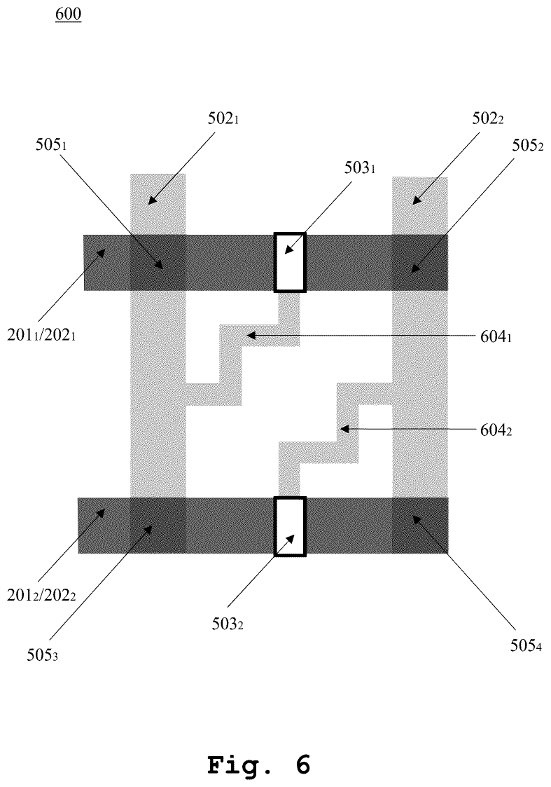

In FIG. 6, a second exemplary embodiment of the second network 600 according to the first aspect of the disclosure is illustrated. The second network 600 may correspond to the corner network of FIG. 1. The second network 600 may differ from the second network 500 in that the first coupling path 6041 and the second coupling path 6042 may have a number of consecutive 90 degrees turns.

For example, the first coupling path 6041 may comprise three successive 90 degrees turns. However, the first coupling path 6041 may comprise more than or less than three 90 degrees turns. In addition, the second coupling path 6042 may comprise three successive 90 degrees turns. However, the second coupling path 6042 may comprise more than or less than three 90 degrees turns.

For example, the first coupling path 6041 may have a smaller width than the width of the first path 5021 of the pair of routing paths. In addition, the second coupling path 6042 may have a smaller width than the width of the second path 5022 of the pair of routing paths. However, the first coupling path 6041 and the second coupling path 6042 may have identical lengths, widths, identical number of turns, and/or identical polygon shapes with respect to each other.

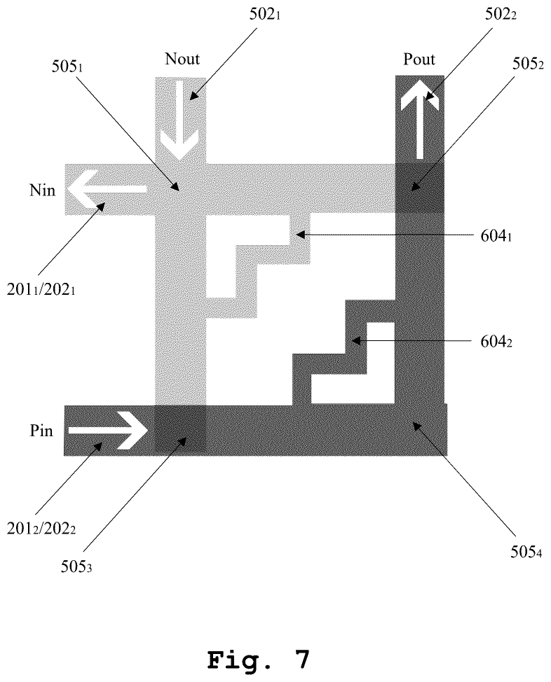

In FIG. 7, an exemplary signal flow for the network 600 is illustrated. In particular, a routing operation of a differential signal Pin, Nin from the pair of distribution paths 2011, 2012 to the pair of routing paths 5021, 5022 is illustrated. In this example, the p-path is shown in the darker grayscale and the n-path is shown in the lighter grayscale.

The negative signal Nin may be inputted from the first path 2011 of the pair of distribution paths and may be routed (shown as Nout) to the first path 5021 of the pair of routing paths via the first coupling path 6041. Similarly, the positive signal Pin may be inputted from the second path 2012 of the pair of distribution paths and may be routed (shown as Pout) to the second path 5022 of the pair of routing paths via the second coupling path 6042.

The signal path Nin-Nout from the first path 2011 of the pair of distribution paths to the first path 5021 of the pair of routing paths and the signal path Pin-Pout from the second path 2012 of the pair of distribution paths to the second path 5022 of the pair of routing paths may have an equivalent electrical length, width, line inductance, and an equivalent amount of coupling capacitance.

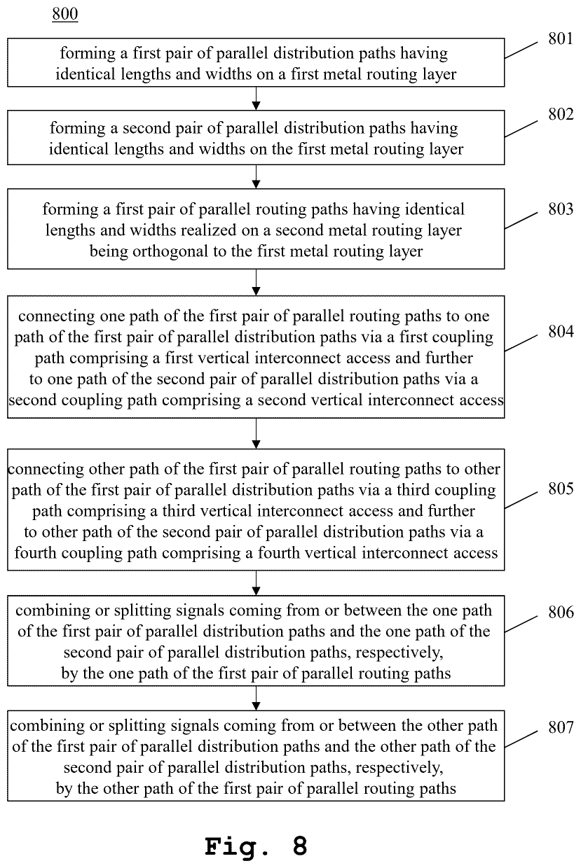

In FIG. 8, an exemplary embodiment of the method 800 according to the second aspect of the disclosure is illustrated. In a first step 801, a first pair of parallel distribution paths having identical lengths and widths is formed on a first metal routing layer. In a second step 802, a second pair of parallel distribution paths having identical lengths and widths is formed on the first metal routing layer. In a third step 803, a first pair of parallel routing paths having identical lengths and widths is formed on a second metal routing layer being orthogonal to the first metal routing layer.

In a fourth step 804, one path of the first pair of parallel routing paths is connected to one path of the first pair of parallel distribution paths via a first coupling path comprising a first vertical interconnect access and further to one path of the second pair of parallel distribution paths via a second coupling path comprising a second vertical interconnect access.

In a fifth step 805, other path of the first pair of parallel routing paths is connected to other path of the first pair of parallel distribution paths via a third coupling path comprising a third vertical interconnect access and further to other path of the second pair of parallel distribution paths via a fourth coupling path comprising a fourth vertical interconnect access.

In a sixth step 806, signals coming from or between the one path of the first pair of parallel distribution paths and the one path of the second pair of parallel distribution paths are combined or split, respectively, by the one path of the first pair of parallel routing paths.

In a seventh step 807, signals coming from or between the other path of the first pair of parallel distribution paths and the other path of the second pair of parallel distribution paths are combined or split, respectively, by the other path of the first pair of parallel routing paths.

It may be noted that, in the description as well as in the claims, the word “comprising” does not exclude other elements or steps and the indefinite article “a” or “an” does not exclude a plurality. A single element or other unit may fulfill the functions of several entities or items recited in the claims.

It may be understood that the term “and/or” used in the specification and the appended claims of this application refers to any combination and (e.g., all) possible combinations of one or more associated listed items, and includes these combinations. It may also be understood that the word “connected” implies that the elements may be directly connected together or may be coupled through one or more intervening elements. Moreover, the disclosure with regard to any of the aspects is also relevant with regard to the other aspects of the disclosure.

Although the disclosure has been illustrated and described with respect to one or more implementations, equivalent alterations and modifications will occur upon the reading and understanding of this specification and the annexed drawings. In addition, while a particular feature of the disclosure may have been disclosed with respect to (e.g., only) one of several implementations, such feature may be combined with one or more other features of the other implementations as may be useful for any given or particular application.

While some embodiments have been illustrated and described in detail in the appended drawings and the foregoing description, such illustrations and description are to be considered illustrative and not restrictive. Other variations to the disclosed embodiments can be understood and effected in practicing the claims, from a study of the drawings, the disclosure, and the appended claims. The mere fact that (e.g., certain) measures or features are recited in mutually different dependent claims does not indicate that a combination of these measures or features cannot be used. Any reference signs in the claims should not be construed as limiting the scope.

What is claimed is:

1. An apparatus for differential signal routing, the apparatus comprises a first network comprising:
a first pair of parallel distribution paths having substantially identical lengths and widths provided on a first metal routing layer,
a second pair of parallel distribution paths having substantially identical lengths and widths provided on the first metal routing layer, and
a first pair of parallel routing paths having substantially identical lengths and widths provided on a second metal routing layer being orthogonal to the first metal routing layer,
wherein one path of the first pair of parallel routing paths is connected to one path of the first pair of parallel distribution paths via a first coupling path comprising a first vertical interconnect access and further to one path of the second pair of parallel distribution paths via a second coupling path comprising a second vertical interconnect access in order to combine or split signals coming from or between the one path of the first pair of parallel distribution paths and the one path of the second pair of parallel distribution paths, respectively,
wherein other path of the first pair of parallel routing paths is connected to other path of the first pair of parallel distribution paths via a third coupling path comprising a third vertical interconnect access and further to other path of the second pair of parallel distribution paths via a fourth coupling path comprising a fourth vertical interconnect access in order to combine or split signals coming from or between the other path of the first pair of parallel distribution paths and the other path of the second pair of parallel distribution paths, respectively,
wherein at least the first coupling path and the third coupling path have substantially identical lengths and widths, and at least the second coupling path and the fourth coupling path have substantially identical lengths and widths.

2. The apparatus according to claim 1,
wherein the first metal routing layer and the second metal routing layer correspond to back-end-of-line, BEOL, metallization structures.

3. The apparatus according to claim 1,
wherein each of the first coupling path and the third coupling path comprises a number of turns identical to each other.

4. The apparatus according to claim 1,
wherein the first coupling path, the second coupling path, the third coupling path, and the fourth coupling path have substantially identical lengths, widths, and identical number of turns.

5. The apparatus according to claim 1,
wherein the first coupling path, the second coupling path, the third coupling path, and the fourth coupling path have identical number of 45 degree turns.

6. The apparatus according to claim 1,
wherein the first coupling path, the second coupling path, the third coupling path, and the fourth coupling path have identical number of 90 degree turns.

7. The apparatus according to claim 1,
wherein the one path of the first pair of parallel routing paths and the first pair of parallel distribution paths overlap at respective cross-sections, and
wherein the other path of the first pair of parallel routing paths and the second pair of parallel distribution paths overlap at respective cross-sections.

8. The apparatus according to claim 1, further comprising
at least one second network comprising:
a second pair of parallel routing paths having substantially identical lengths and widths provided on the second metal routing layer, and
a pair of vertical interconnect accesses being symmetrically arranged on the first metal routing layer with respect to the lengths of the first pair of parallel distribution paths or the second pair of parallel distribution paths.

9. The apparatus according to claim 8,
wherein the widths of the second pair of parallel routing paths and the widths of the pair of coupling paths are substantially identical to each other.

10. The apparatus according to claim 8,
wherein the widths of the second pair of parallel routing paths and the widths of the pair of coupling paths are different from each other.

11. The apparatus according to claim 8,
wherein each path of the pair of coupling paths comprises a number of turns identical to each other, such as a number of 45 degree turns.

12. The apparatus according to claim 8,
wherein each path of the pair of coupling paths comprises a number of turns identical to each other, such as a number of 90 degree turns.

13. The apparatus according to claim 8,
wherein the second pair of parallel routing paths and the first pair of parallel distribution paths overlap at their respective cross-sections.

14. The apparatus according to claim 8,
wherein the second pair of parallel routing paths are respectively connected to the pair of vertical interconnect accesses via a pair of coupling paths having substantially identical lengths provided on the second metal routing layer.

15. The apparatus according to claim 14, the pair of coupling paths being symmetrically connected to the second pair of parallel routing paths with respect to the lengths of the second pair of parallel routing paths in order to couple in or out a differential signal to or from the first pair of parallel distribution paths or the second pair of parallel distribution paths, respectively.

16. The apparatus according to claim 8,
wherein each vertical interconnect access of the pair of vertical interconnect accesses is arranged on a distribution path of the first pair of parallel distribution paths.

17. The apparatus according to claim 1, wherein each of the second coupling path and the fourth coupling path comprises a number of turns identical to each other.

18. The apparatus according to claim 8,
wherein each vertical interconnect access of the pair of vertical interconnect accesses is arranged on a distribution path of the second pair of parallel distribution paths.

19. The apparatus according to claim 8,
wherein the second pair of parallel routing paths are respectively connected to the pair of vertical interconnect accesses via a pair of coupling paths having substantially identical widths provided on the second metal routing layer.

20. The apparatus according to claim 8,
wherein the second pair of parallel routing paths and the second pair of parallel distribution paths overlap at their respective cross-sections.
